(19) United States
(12) Patent Application Publication
(10) Pub. No.: US 2003/0025490 A1
(43) Pub. Date: Feb. 6, 2003

(54) Method for verifying hardware circuits through simulation

(76) Inventor: Tzu-Pei Chen, Taipei Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/063,208

(22) Filed: Mar. 28, 2002

(30) Foreign Application Priority Data
Aug. 2, 2001 (TW) 090118934

(51) Int. Cl. G06F 17/50; G01R 1/00

(52) U.S. Cl. 324/112

(57) ABSTRACT

A method for verifying a device under test includes inputting a control command, compiling the control command to a corresponding data-bus command, and simulating the result generated by the device under test after executing the data-bus command and comparing the result with an expected value. The method allows the tester to input readable hardware control commands with various methods, rather than to perform a simulation test by inputting unreadable data-bus control commands.

### BACKGROUND OF INVENTION

1. Field of the Invention

The present invention relates to a method for verifying the logic design of a hardware circuit, and more specifically, the present invention discloses a method for conveniently compiling testing items with a hardware control command.

2. Description of the Prior Art

With the rapid development of electronic circuits, processing electronic information with various electronic circuits and microprocessors has quickly become a core technique of the modern information industry, and is thus a foundation of modern information society. A typical information processing system, such as a small mobile phone, a personal digital assistant (PDA), and even a complete computer system, all utilize various electronic circuits to process digital electronic information.

Generally speaking, the electronic circuits or the microprocessor chip in the information processing system, particularly in the computer system, operate according to standardized hardware control commands so that the specifications for information processing is united. In order to gather and coordinate the functionality of each electronic circuit in the information processing system, a bus between each electric circuit is utilized to exchange information, commands, and signals. The electric signals exchanged on the buses need to be compatible with a specific format of the bus command, too. Therefore, the electronic circuit receives the bus command first, then compiles the command into a corresponding hardware control command, and then operates according to the hardware control command. For example, the hard disk drive or the compact disk drive in a computer system utilizes a control chip (or a controller) to control data access. When the central processing unit (CPU) writes data to the hard disk drive or the compact disk drive, or reads data from the hard disk drive or the compact disk drive, the CPU will transmit the data-bus command compatible with the format of the bus command (such as the industrial EIDE standard format bus command) to the control chip through the buses. Then the control chip compiles the data-bus command into a hardware control command (such as the industrial ATAPI standard format command, with ATAPI meaning AT Attachment Packet Interface) to initiate the hard disk drive or the compact disk drive for corresponding data accessing.

To ensure adequate functionality of the electronic circuit, a circuit designer needs to verify the designed circuit through a computer aided design (CAD) software simulation after finishing the design, so as to ensure that the circuit operates properly and correctly according to the desired functionality. Since what the electronic circuit or the control chip actually receives are the data-bus command with hardware control command embedded, then the computer simulation test is to test if the simulated electronic circuits, after receiving the data-bus command, properly execute the action corresponding to the hardware control command within the data-bus command. In the prior art method, the tester performing a computer simulation needs to list the testing items as data-bus commands, and then input the data-bus commands into the computer for simulation in order to perform the computer simulated testing. However, the format of the data-bus command is a low-level language format, which is designed to allow the signals and commands to be exchanged and transmitted on the buses conveniently and efficiently, not designed for readability. Furthermore, the data-bus commands are usually lengthy, and not understandable. Not only does the manual input take a lot of time, but also the format is unfriendly and apt to result in misunderstanding and mistakes.

### SUMMARY OF INVENTION

It is therefore a primary objective of the claimed invention to provide a method for verifying logic design of a hardware circuit with an interface program. The user (tester) utilizes simple hardware control commands to generate a hardware control command file through the interface program, and converts the hardware control command file into a corresponding data-bus command through a compiling program in order to simplify the testing procedure of electronic circuits and to overcome the drawbacks of the prior art.

The claimed invention, briefly summarized, discloses a method for verifying a device under test. The method includes inputting a control command, compiling the control command into a corresponding data-bus command, and simulating the result generated by the device under test after executing the data-bus command and comparing the result with an expected value.

It is an advantage of the claimed invention that the claimed invention utilizes an interface program to perform a simulation test for the logic design of an electronic circuit conveniently. The interface program allows the tester to input the readable hardware control commands with various methods (such as to input them directly, to modify an existing file with control commands, or to select them from the command base), rather than to perform the simulation test by inputting unreadable data-bus control commands. These hardware control commands are compiled into the corresponding data-bus commands through a transfer program, and are then input into a simulation program. The simulation program will perform a simulation test according to these data-bus commands to verify the tested circuit through simulation. The method for verifying the circuits is much easier to operate than the prior art method. By utilizing the stored hardware control command file, the existing hardware control command file is loaded anytime and is readily modified to fulfill the requirement of various testing items. The time required for performing the simulation to verify an electronic circuit is thus reduced. Not only the correctness for the electronic circuit design is ensured, but also the time and cost for the simulation test is reduced. In addition, the tester will accumulate more and more experience and knowledge about simulation tests by storing and utilizing the readable hardware control command file.

These and other objectives and advantages of the claimed invention will no doubt become obvious to those of ordinary skill in the art after reading the following detailed description of the preferred embodiment that is illustrated in the various figures and drawings.

### BRIEF DESCRIPTION OF DRAWINGS

FIG. 1 illustrates a flow chart of the present invention method.

FIG. 2A is a schematic diagram of a window interface of the interface program according to the preferred embodiment of the present invention.

FIG. 2B is a schematic diagram of a command option shown in FIG. 2A.

FIG. 2C is a schematic diagram of another command option shown in FIG. 2A.

### DETAILED DESCRIPTION

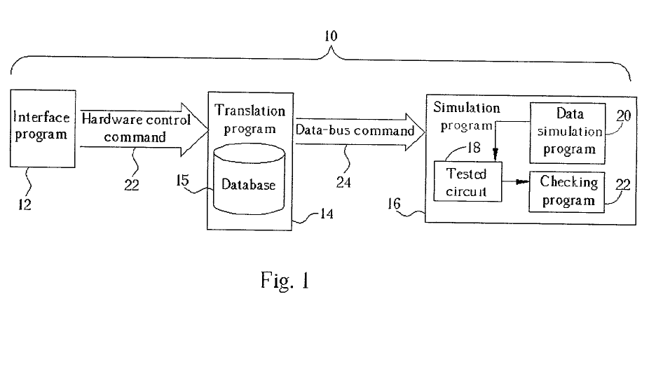

Please refer to FIG. 1. FIG. 1 illustrates a flow chart of a method 10 for verifying a hardware circuit by a computer according to the present invention. The method 10 for verifying a hardware circuit is performed on a computer (not shown). The computer executes an interface program 12, a translation program 14, and a simulation program 16 to simulate the action of a tested circuit 18. The tested circuit 18 may be a control chip for a hard disk drive or a compact disk drive. The interface program 12 is utilized to generate hardware control commands 22 (such as the ATAPI standard format hardware control command), and input the hardware control command 22 into the translation program 14. The translation program 14 compiles the hardware control command 22 into a corresponding data-bus command 24 (such as the industrial EIDE standard format) and inputs the data-bus command 24 into the simulation program 16. As described above, the simulation program 16 will simulate the response of the tested circuit 18, which receives the data-bus command 24, to verify the circuit design of the tested circuit 18. In addition, a database 15 is built in the translation program 14 to store a mapping relationship between the hardware control command and the data-bus command. As known in industry, one hardware control command is described by several data-bus commands. In the prior art method, the tester needs to input the data-bus commands to the simulation program manually. In the present invention, the mapping relationship between the hardware control command and the data-bus command is stored in the database 15. Thus the translation program 14 can utilize the database 15 to compile the hardware control command into the corresponding data-bus command. In addition, the tester can input the testing items of the tested circuit 18 into the interface program 12 directly with a simple and readable hardware control command. Next, the translation program 14 compiles the hardware control command into the data-bus command to perform simulation tests. Therefore, the tester does not need to input the lengthy, complex, and unreadable data-bus commands.

Moreover, the simulation program 16 will execute an attached data simulation program 20 and a checking program 22. If the tested circuit 18 is a control chip for a compact disk drive or a hard disk drive, it is necessary to simulate a control process of the control chip for controlling the compact disk drive or hard disk drive to execute a read/write operation. Since there is actually no physical disk drive for the simulated control chip to control, the data simulation program 20 is executed to simulate the disk drive instead. In such case, the simulation program 16 will execute the data simulation program 20 to acquire the data obtained from simulating the control process for the control chip to control the compact disk drive or the hard disk drive. The checking program 22 attached in the simulation program 16 will receive resultant action after the simulation program 16 simulates the operation of the tested circuit 18, and will check if the action matches an expected result. If the resultant action does not match the expected result, there is something wrong with the design of the tested circuit 18, and trouble-shooting needs to be performed. If the resultant action matches the expected result, the design of the tested circuit 18 fulfills expectations.

When performing the present invention method practically, each program may store necessary files for the purpose of tracing the executing process. For example, after the tester uses hardware control language to input the testing items into the interface program 12, the interface program 12 can store the testing items in a specific hardware control command file for later tracing. The tester can modify or re-compile the hardware control command file, through the interface program 12, to perform other testing items. The data-bus command, obtained by compiling the hardware control command or the hardware control command file with the translation program 14, can also be stored in a specific data-bus command file (or the compiled data-bus command and the original hardware control command can be stored in the same file). Thus, it is convenient to trace and debug the execution process of the present invention method. In addition, the data simulation program 20 can read/write the hardware control command file to generate the data necessary for the simulation process (the data acquired from the control process of the control chip for controlling the hard disk drive or the compact disk drive to execute a read/write operation as described previously).

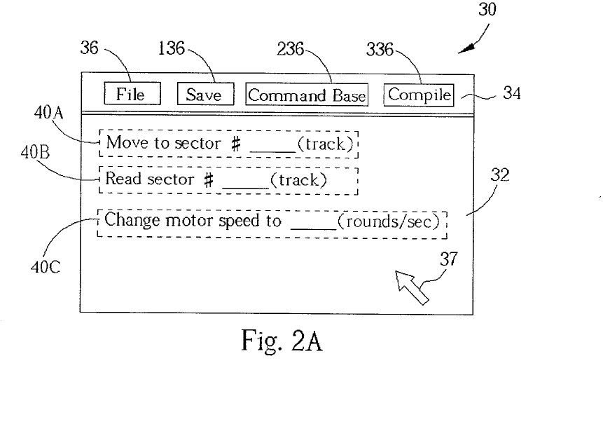

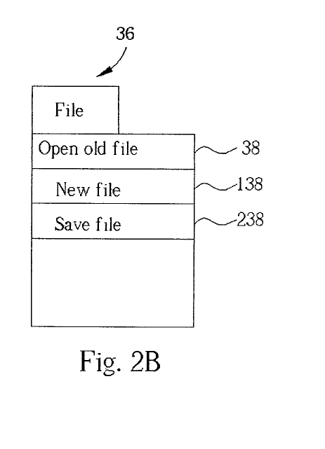

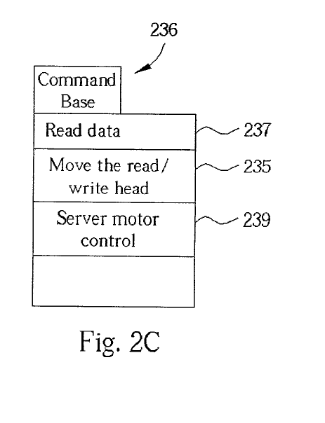

Please refer to FIG. 2A. FIG. 2A is a schematic diagram of a window interface 30 of the interface program according to the preferred embodiment of the present invention. The window interface 30 comprises a command input area 32 and a command menu 34. The command menu 34 comprises command options 36, 136, 236, and 336. The user may input the hardware control command (such as the hardware control command 40A, 40B, or 40C) into the command input area 32 in the window interface 30 of the interface program 12 directly. To open a hardware control command file or to load a stored hardware control command file, the command option 36 “File” is chosen in the command menu 34. Moreover, templates for a hardware control command file can be loaded and modified (such as filling in the blanks 40A, 40B, 40C in the hardware control command) to execute various simulation tests. The command option 136 “Save” will store the hardware control command in the command input area 32 into a specific hardware control command file. The command option 336 “Compile” will compile the hardware control command in the command input area 32 into the corresponding data-bus command with the translation program 14 and perform the simulation test.

The above-mentioned compiling of the hardware control command includes opening a hardware command file, storing the file, and modifying the file. These functions can be realized by utilizing a mouse cursor 37 or by utilizing a keyboard (not shown).

Please refer to FIG. 2B to FIG. 2C. FIG. 2B and FIG. 2C are schematic diagrams of command options 36 and 236 in FIG. 2A. The command option 36 “File” is a pull-down command menu. The pull-down command menu comprises at least one subcommand option, such as “Open old file” 38, “Open new file” 138, or “Save file” 238, which allows the interface program 12 to open an existing hardware control command file, to build a new hardware control command file, and to store the hardware control command file under editing, respectively. The command option “Command Base” 236 further comprises subcommands which represent different hardware control commands. For example, the subcommand options 237, 235, and 239 represent “Read data”, “Move the read/write head”, and “Server motor control”, respectively. These subcommand options 237, 235, and 239 of the command base will form at least one hardware control command in the command input area 32 shown in FIG. 2A after being selected (or form several hardware control commands, for example: to select “Read data” will generate hardware control commands 40A, 40B in the command input area 32). After these hardware control commands are built, a hardware control command file is grouped to record the hardware control command necessary for performing one specific testing item. The command option “Compile” 336 shown in FIG. 2A is then utilized to compile the hardware control command file into a corresponding data-bus command, with a standardized process by a compiling program, and execute the simulation test. The checking program 22 in the simulation program 16 will check if the simulated tested circuit 18 executes the corresponding command properly and generates a corresponding actionafter receiving the data-bus command, and shows the checking result to the tester through the interface program 12.

For instance, assume the tested circuit 18 is a control chip for a compact disk drive, and the hardware control command is such a hardware control command as “Move to sector #12” 40A and “Read sector #12” 40B as shown in FIG. 2A.The interface program 12 will compile the two hardware control commands into the corresponding data-bus commands with the translation program 14, and perform a simulation with the simulation program 16 after the command option “Compile” 336 is selected. The data simulation program 20 will generate the data in sector #12 by simulating the control process for the control chip to control the compact disk drive so as to execute a read operation in sector #12 of the compact disk. The data is then transmitted to the tested circuit 18 in the simulation program 16 to simulate that the control chip receives the data in sector #12 transmitted from the compact disk drive. The data is also transmitted to the checking program 22 as a reference for comparing with the simulation result. The checking program 22 will check the data processing result of the tested circuit (which means the data in sector #12), and compares with the data generated by the data simulation program 20 firsthand to evaluate if the tested circuit 18 processes data properly according to the hardware control command. The evaluation result will be transmitted to the interface program 12 so the tester can observe the result of the simulation test. The present invention method not only applies to the simulation test of the control chip for the compact disk drive, but also applies to the control chip for other periphery devices, such as network cards, keyboards, and mice. As with the control chip for the compact disk drive, these periphery devices need to exchange data with the CPU through buses. Therefore, it is necessary for the control chip for these periphery devices to compile the data-bus command into the hardware control command. So the present invention method is also useful to simulate and test the control chips for these periphery devices.

In contrast to the prior art method, the present invention method comprises an interface program for conveniently testing the logic design of electronic circuits. The interface program allows the tester to input the readable hardware control commands with various methods (such as to input them directly, to modify an existing file with hardware control commands, or to select them from the command base), rather than to perform the simulation test by inputting unreadable data-bus control commands. These hardware control commands are compiled into the corresponding data-bus commands through a transfer program, and are input into a simulation program. The simulation program will perform a simulation test according to these data-bus commands to verify the tested circuit through simulation. The presented method for verifying the circuits is much easier to operate than the prior art method. By utilizing the stored hardware control command file, the existed hardware control command file can be loaded anytime and is readily modified to fulfill the requirements of various testing items. The time required for performing the simulation to verify an electronic circuit is then reduced. Not only is the correctness for the electronic circuit design ensured, but also the time and cost for the simulation test is reduced. In addition, the tester will accumulate more and more experience and knowledge about simulation test by utilizing the stored readable hardware control command file.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method forverifying device under test, said method comprising:
inputting a control command;
compiling said control command into a corresponding data-bus command; and
simulating said result generated by said device under test after executing said data-bus command and comparing said result with an expected value.

2. The method of claim 1 wherein said device under test is a controller of a compact disk drive.

3. The method of claim 2 wherein said simulation said step further comprises:
simulating a control process of said controller for controlling said compact disk drive to execute a read/write operation on a compact disk.

4. The method of claim 1 further comprising:
storing said simulation result.

5. The method of claim 1 further comprising:
storing said control command.

6. The method of claim 1 wherein said control command is an AT Attachment Packet Interface (ATAPI) command.

7. The method of claim 1 wherein said data-bus command conforms to a bus standard of a computer system.

8. The method of claim 1 wherein said compiling step further comprises:
building a database for storing a mapping relationship between said data-bus command and said control command.
